(19) United States
(12) Patent Application Publication
(10) Pub. No.: US 2025/0215555 A1
(43) Pub. Date: Jul. 3, 2025

(54) METHODS AND ASSEMBLIES FOR SELECTIVE DEPOSITION OF METAL-CONTAINING MATERIAL

(71) Applicant: ASM IP Holding B.V., Almere (NL)

(72) Inventors: Saima Ali, Helsinki (FI); Bhagyesh Purohit, Helsinki (FI); Eva E. Tois, Espoo (FI); Marko Tuominen, Helsinki (FI); Yu Xu, Mesa, AZ (US); Charles Dezelah, Helsinki (FI)

(21) Appl. No.: 19/000,941

(22) Filed: Dec. 24, 2024

Related U.S. Application Data
(60) Provisional application No. 63/615,659, filed on Dec. 28, 2023.

(51) Int. Cl. C23C 16/04; C23C 16/34; C23C 16/40

(52) U.S. Cl. CPC C23C 16/04; C23C 16/34; C23C 16/403

(57) ABSTRACT

The current disclosure relates to methods and assemblies for selectively depositing metal-containing materials, such as metal oxides, on different surfaces of a semiconductor substrate by cyclic vapor deposition techniques, including atomic layer deposition. The metal-containing material is deposited using a metal precursor having a metal atom bound to an acetamidinato ligand, such as dialkylacetamidinato ligand. The metal-containing material may be deposited on a metal surface relative to a dielectric surface, or to a dielectric surface relative to a metal surface, depending on the process flow. The current disclosure further relates to layers, structures and semiconductor devices deposited according to the methods disclosed herein, as well as to semiconductor processing assemblies configured and arranged to perform said methods.

### CROSS-REFERENCE TO RELATED APPLICATION(S)

This Application claims the benefit of U.S. Provisional Application 63/615,659 filed on Dec. 28, 2023, the entire contents of which are incorporated herein by reference.

### FIELD

The present disclosure generally relates to methods and assemblies selectively depositing metal-containing material by cyclic vapor deposition techniques. Such methods may be used for, for example, processing semiconductor substrates. More particularly, the disclosure relates to methods and assemblies for selectively depositing a metal-containing material.

### BACKGROUND

Semiconductor device fabrication processes generally use advanced vapor deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing, by, for example, reducing the number of patterning and etching steps. Selective deposition could also allow enhanced scaling in narrow structures. The ability to choose the deposition surface between dielectric materials and conductive materials, such as metals, may particularly simplify device fabrication process flows. Thermal deposition methods may be preferred over plasma-enhanced methods, due to better compatibility with sensitive materials. However, typically the quality of thermally deposited metal-containing materials, such as their electrical properties or etching resistance, may be lower than of metal-containing materials deposited using plasma.

Metal-containing materials, such as metal oxides and metal nitrides, may be used for various purposes, for example as dielectric layers, etch stop layers and barriers to diffusion in semiconductor devices. Various alternatives for bringing about selective deposition of metal-containing materials have been proposed, and additional improvements are needed to expand the use of selective deposition in industrial-scale device manufacturing, particularly for producing high-quality materials using thermal deposition methods.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of depositing metal-containing materials, and in particularly selectively depositing metal oxides, metal nitrides and metal fluorides. Embodiments of the current disclosure further relate to methods of fabricating semiconductor devices, and to semiconductor processing assemblies.

Various embodiments of the current disclosure relate to selective deposition of metal-containing materials, such as dielectric layers, including metal oxides, metal nitrides and metal fluorides. In particular, the disclosure relates to the deposition of aluminum-, gallium- and indium-containing materials by cyclic vapor deposition processes. The metal-containing materials may include doped metal-containing materials, such as yttrium-doped aluminum oxide (AlYOx), aluminum gallium nitride (AlGaN) or indium aluminum nitride (InAlN). Embodiments of the current disclosure further relate to structures formed using the methods and processing assemblies.

In one aspect, a method of selectively depositing a metal-containing material on a first surface of a semiconductor substrate relative to the second surface of the substrate is disclosed. The method comprises providing the substrate in a reaction chamber and depositing the metal-containing material on the first surface of the substrate by a cyclic vapor deposition process. The vapor deposition process comprises providing a first metal precursor into the reaction chamber in a vapor phase and providing a reactant into the reaction chamber in a vapor phase, wherein the first metal precursor comprises a heteroleptic precursor comprising a group 13 metal atom, an amidinato ligand and an alkyl ligand attached to the metal atom.

In some embodiments, the metal of the metal-containing material is selected from a group consisting of aluminum (Al), gallium (Ga) and indium (In). In some embodiments, the first metal precursor is selected from a group consisting of aluminum precursor, gallium precursor and indium precursor.

In some embodiments, the metal-containing material is aluminum oxide (such as Al₂O₃), and the first metal precursor is an aluminum precursor. In some embodiments, the metal-containing material is gallium oxide (such as Ga₂O₃), and the first metal precursor is a gallium precursor. In some embodiments, the metal-containing material is indium oxide (such as In₂O₃), and the first metal precursor is an indium precursor.

In some embodiments, the metal-containing material is aluminum nitride, and the first metal precursor is an aluminum precursor. In some embodiments, the metal-containing material is gallium nitride, and the first metal precursor is a gallium precursor. In some embodiments, the metal-containing material is indium nitride, and the first metal precursor is an indium precursor.

In some embodiments, the alkyl ligand attached to the metal atom is selected from a group consisting of methyl, ethyl and linear or branched alkyl groups containing three, four or five carbon atoms. In some embodiments, the first metal precursor comprises two alkyl ligands bonded to the metal atom.

In some embodiments, the amidinato ligand comprises an acetamidinato ligand. In some embodiments, the acetamidinato ligand is an alkylacetamidinato ligand. In some embodiments, the alkylacetamidinato ligand is a dialkylacetamidinato ligand. In some embodiments, the one or two alkyl groups of the alkylacetamidinato ligand are selected from a group consisting of methyl, ethyl, n-propyl, isopropyl, n-butyl, tert-butyl and sec-butyl.

In some embodiments, the first metal precursor is selected from a group consisting of N,N′-di-(isopropylformamidinato)dimethylaluminum, N,N′-di-(isopropylformamidinato)diethylaluminum, N,N′-di-(isopropylformamidinato)-di-n-propylaluminum, N,N′-di-(isopropylformamidinato)-di-tert-butylaluminum and N,N′-di-(isopropylformamidinato)ethylmethylaluminum.

In some embodiments, the reactant selected from a group consisting of oxygen precursors, nitrogen precursors and fluorine precursors. In some embodiments, the reactant is selected from molecular oxygen, ozone, hydrogen peroxide and water. In some embodiments, the reactant is selected from NH₃ and N₂H₄. In such embodiments, the metal-containing material is metal nitride. In some embodiments, the reactant is selected from HF, NH₄F, TiF₄ and WF₆. In such embodiments, the metal-containing material is metal fluoride.

In some embodiments, a second metal precursor is provided into the reaction chamber to deposit a metal-containing material comprising two different metals. In some embodiments, the deposited metal-containing material has a thickness from about 0.03 nm to about 10 nm.

In some embodiments, the first surface is a dielectric surface.

In some embodiments, the dielectric surface comprises silicon. In some embodiments, the dielectric surface comprises material selected from a group consisting of SiO₂, SIN, SiC, SiOC, SiON, SiOCN, SiGe and combinations thereof.

In some embodiments, the dielectric surface comprises a metal oxide. In some embodiments, the metal oxide of the second surface is selected from aluminum oxide, hafnium oxide and zirconium oxide.

In some embodiments, the second surface is a conductive surface. In some embodiments, the second surface comprises a material selected from a group consisting of a metal, amorphous carbon, metal oxide and metal nitride. In some embodiments, the second surface comprises elemental metal. In some embodiments, the metal of the second surface is selected from a group consisting of Cu, Co, Ru, W, Ti, Al, Ta, Nb and Mo.

In some embodiments, the second surface comprises passivation. In some embodiments, the passivation comprises a passivation layer on the second surface. In some embodiments, the passivation layer comprises an organic polymer. In some embodiments, the organic polymer comprises polyimide.

In some embodiments, the method comprises, before providing the first metal precursor into the reaction chamber, treating the first surface with an inhibitor reactant and thereafter depositing an organic polymer on the second surface. The organic polymer is deposited on the second surface to passivate the second surface In some embodiments, the method comprises, before providing the first metal precursor into the reaction chamber, treating the first surface with a silylation agent, and thereafter depositing an organic polymer on the second surface.

In some embodiments, the first surface is an elemental metal surface. In some embodiments, the metal of the elemental metal surface is selected from a group consisting of Cu, Co, Ru, W, Ti, Al, Ta, Nb and Mo. In some embodiments, the second surface is a dielectric surface. In some embodiments, the second surface is a metal oxide surface or a silicon-comprising surface. In some embodiments, the second surface comprises a passivation formed by silylating the second surface. In some embodiments, the second surface comprises a passivation formed by treating the second surface with a metal halide, such as NbF₅. In some embodiments, the second surface comprises inhibition formed by treating the second surface with an inhibitor reactant.

In another aspect, a semiconductor processing assembly for selectively depositing a metal-containing material on a first surface of a substrate relative to the second surface of the substrate is disclosed. The semiconductor processing assembly comprises one or more reaction chambers constructed and arranged to hold the substrate and a precursor injector system constructed and arranged to provide a first metal precursor comprising a metal atom bound to an acetamidinato ligand and a reactant into the reaction chamber in a vapor phase. The semiconductor processing assembly further comprises a first metal precursor source vessel constructed and arranged to contain the first metal precursor and an reactant source vessel constructed and arranged to contain the reactant. The semiconductor processing assembly is constructed and arranged to provide the first metal precursor and the reactant via the precursor injector system into the reaction chamber for selectively depositing metal-containing material on the first surface of the substrate.

In some embodiments, the semiconductor processing assembly further comprises one or more passivation source vessels, and wherein the precursor injector system is constructed and arranged to provide one more passivation agents into the reaction chamber in a vapor phase before providing the first metal precursor into the reaction chamber.

In one aspect, a semiconductor processing assembly constructed and arranged to perform a method according to the current disclosure is disclosed.

The term dielectric is used in the description herein for the sake of simplicity in distinguishing from metal or metallic surfaces. It will be understood by those skilled in the art that not all non-conducting surfaces are dielectric surfaces. For example, the metal or metallic surface may comprise an oxidized metal surface that is electrically non-conducting or has a very high resistivity. Selective deposition processes taught herein can deposit on dielectric surfaces with minimal deposition on such adjacent non-conductive metal or metallic surfaces.

For embodiments in which one surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal-containing materials, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum (Al). In some embodiments, a metal or metallic surface comprises copper (Cu). In some embodiments, a metal or metallic surface comprises tungsten (W). In some embodiments, a metal or metallic surface comprises cobalt (Co). In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises molybdenum (Mo). In some embodiments, a metal or metallic surface comprises a metal selected from a group consisting of Al, Mn, Fe, Co, Ni, Cu, Zn, Nb, Mo, Ru and W. In some embodiments, the metal or metallic surface comprises a transition metal selected from a group consisting of Zn, Fe, Mn and Mo.

In some embodiments, a metallic surface comprises titanium nitride. In some embodiments, the metal or metallic surface comprises one or more noble metals, such as Ru. In some embodiments, the metal or metallic surface comprises a conductive metal-containing material. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN)

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The term “essentially” as applied to a composition, a method, or a system generally means that the additional components do not substantially modify the properties and/or function of the composition, the method, or the system.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings

FIG. 1 is a block diagram of an exemplary embodiment of a method according to the current disclosure.

FIG. 2 is a block diagram of another exemplary embodiment of a method according to the current disclosure.

FIG. 3 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, layers, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

In one aspect, a method of selectively depositing a metal-containing material on a first surface of a semiconductor substrate relative to the second surface of the substrate is disclosed. The metal-containing material may be deposited as a layer. As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer according to the current disclosure is continuous.

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device. A substate according to the current disclosure comprises a first surface and a second surface. The first surface and the second surface have different material properties, allowing for the selective deposition of a metal-containing material, such as metal oxide, metal nitride or metal fluoride, on the first surface.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

The method comprises providing the substrate in a reaction chamber and depositing the metal-containing material on the first surface of the substrate by a cyclic vapor deposition process. The method of depositing metal-containing material according to the current disclosure thus comprises providing the substrate in a reaction chamber. In other words, the substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single wafer atomic layer deposition (ALD) reactor. In some embodiments, the reaction chamber may be a high-volume manufacturing single wafer ALD reactor. In some embodiments, the reaction chamber may be a batch reactor for manufacturing multiple substrates simultaneously.

The reaction chamber can form part of an ALD assembly. The reaction chamber can form part of a chemical vapor deposition (CVD) assembly. The deposition assembly may be an ALD or a CVD deposition assembly, but in certain process steps, molecular layer deposition (MLD) may also be employed in some parts of the deposition process flows. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors.

The vapor deposition process according to the current disclosure is a cyclic deposition process. Generally, in cyclic deposition processes according to the current disclosure, such as ALD and MLD, during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor, such as a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a first precursor into the reaction chamber. In some embodiments, the cyclic deposition process comprises purging the reaction chamber after providing a second precursor into the reaction chamber. In some embodiments, the cyclic deposition process comprises purging the reaction chamber after providing a first precursor into the reaction chamber, and after providing second precursor into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, whereas in MLD, the precursors may be fully organic molecules.

The process may comprise one or more cyclic phases. In some embodiments, the process comprises or one or more acyclic (i.e. continuous) phases. In some embodiments, the deposition process comprises the continuous flow of at least one precursor. In such an embodiment, the process comprises a continuous flow of a first metal precursor or a reactant. In some embodiments, one or more of the precursors and reactants are provided in the reaction chamber continuously.

The vapor deposition process according to the current disclosure comprises providing a first metal precursor into the reaction chamber in a vapor phase and providing a reactant into the reaction chamber in a vapor phase. In some embodiments, at least one of first metal precursor and reactant is provided to the reaction chamber in pulses. In some embodiments, the first metal precursor is supplied in pulses and the reactant is supplied in pulses, and the reaction chamber is purged between consecutive pulses of first metal precursor and reactant. A duration of providing first metal precursor and/or a reactant into the reaction chamber (i.e. first precursor pulse time and reactant pulse time, respectively) may be, for example, from about 0.01 s to about 60 s, for example from about 0.1 s to about 10 s, or from about 0.5 s to about 20 s, or from about 0.5 s to about 10 s, or from about 2 s to about 15 s, or from about 10 s to about 30 s, or from about 10 s to about 60 s, or from about 20 s to about 60 s. The duration of first metal precursor or a reactant pulse may be, for example 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, first metal precursor pulse time may be at least 5 seconds, or at least 10 seconds. In some embodiments, first metal precursor pulse time may be at most 5 seconds, or at most 10 seconds or at most 20 seconds, or at most 30 seconds. In some embodiments, reactant pulse time may be at least 5 seconds, or at least 10 seconds, or at least 20 seconds. In some embodiments, reactant pulse time may be at most 5 seconds, or at most 10 seconds or at most 20 seconds, or at most 30 seconds.

The pulse times for first metal precursor, and for reactant can vary independently according to process in question. The selection of an appropriate pulse time may depend on the substrate topology. For higher aspect ratio structures, longer pulse times may be needed to obtain sufficient surface saturation in different areas of a high aspect ratio structure. Also the selected first metal precursor and reactant chemistries may influence suitable pulsing times. For process optimization purposes, shorter pulse times might be preferred as long as appropriate layer properties can be achieved. In some embodiments, first metal precursor pulse time is longer than reactant pulse time. In some embodiments, reactant pulse time is longer than first metal precursor pulse time. In some embodiments, first metal precursor pulse time is the same as reactant pulse time.

In some embodiments, providing first metal precursor and/or a reactant into the reaction chamber comprises pulsing the first metal precursor and the reactant over a substrate. In certain embodiments, pulse times in the range of several minutes may be used for the first metal precursor and/or the reactant. In some embodiments, first metal precursor may be pulsed more than one time, for example two, three or four times, before a reactant is pulsed to the reaction chamber. Similarly, there may be more than one pulse, such as two, three or four pulses, of a reactant before first metal precursor is pulsed (i.e. provided) into the reaction chamber.

A pulse of a first metal precursor and a reactant may together form a deposition cycle. As described above, the process is a cyclic deposition process. Thus, providing (i.e. pulsing) the precursors into the reaction chamber is repeated. The pulses may be repeated as desired, depending on, for example, on the growth rate of the metal-containing material, and on the intended thickness of the metal-containing material. In some embodiments, the growth rate of the metal-containing material is from about 0.1 Å/cycle per cycle to about 6 Å/cycle. In some embodiments, the growth rate of the metal-containing material is from about 0.1 Å/cycle to about 3 Å/cycle, such as about 0.1 Å/cycle or about 0.5 Å/cycle. In some embodiments, the growth rate of the metal-containing material is from about 0.1 Å/cycle to about 1 Å/cycle, such as about 0.7 Å/cycle or about 0.9 Å/cycle. In some embodiments, the growth rate of the metal-containing material is from about 0.5 Å/cycle to about 2 Å/cycle, such as about 0.2 Å/cycle or about 0.3 Å/cycle or about 1.5 Å/cycle. In some embodiments, the growth rate of the metal-containing material is from about 1 Å/cycle to about 4 Å/cycle, such as about 3 Å/cycle.

The metal-containing material thickness may be selected according to the application in question. In some embodiments, the deposited metal-containing material has a thickness from about 0.03 nm to about 10 nm. Thus, depending on the growth rate of the metal-containing material, the deposition cycle may be performed from about 2 to about 800 times. For example, a deposition cycle may be performed about 2, 3, 5, 7, 10, 13, 15, 20, 40, 50, 100, 200, 300, 500 or 600 times.

In some embodiments, the metal-containing material according to the current disclosure is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr. For example, the metal-containing material may be deposited at a pressure of about 1 Torr, about 3 Torr, about 6 Torr, about 8 Torr, about 9 Torr, about 12 Torr or about 18 Torr.

In some embodiments, the cyclic deposition process according to the current disclosure comprises a thermal deposition process. In thermal deposition, the chemical reactions are promoted by increased temperature relevant to ambient temperature. Generally, temperature increase provides the energy needed for the formation of the target material in the absence of other external energy sources, such as plasma, radicals, or other forms of radiation. In some embodiments, the method according to the current disclosure comprises a plasma-enhanced deposition method, for example PEALD or PECVD. For example, in some embodiments, the metal-containing material deposition may be performed by PEALD or PECVD.

In some embodiments, a second metal precursor is provided into the reaction chamber. The second metal precursor may contain the same metal as the first metal precursor or a different metal. In embodiments, in which the second metal precursor comprises a different metal than the first metal precursor, the metal-containing material comprises two metals. In some embodiments, the metal-containing material comprises mostly the first metal and second metal is used as a dopant. Thus, in some embodiments, a second metal precursor is provided into the reaction chamber to deposit a metal-containing material comprising two different metals. In some embodiments, a deposition cycle comprises providing a second metal precursor into the reaction chamber. The second metal precursor may be used to dope the metal-containing material to amend its properties according to the specific application. The second metal precursor may be, for example yttrium (Y), or a second metal selected from the group consisting of Al, In and Ga.

In the methods according to the current disclosure, the first metal precursor comprises a heteroleptic precursor comprising a group 13 metal atom, an amidinato ligand and an alkyl ligand attached to the metal atom. In some embodiments, the metal of the metal-containing material is selected from a group consisting of aluminum (Al), gallium (Ga) and indium (In). In some embodiments, the first metal precursor is selected from a group consisting of aluminum precursor, gallium precursor and indium precursor.

In some embodiments, the metal-containing material is aluminum oxide, and the first metal precursor is an aluminum precursor. In some embodiments, the metal-containing material is gallium oxide, and the first metal precursor is a gallium precursor. In some embodiments, the metal-containing material is indium oxide, and the first metal precursor is an indium precursor. In some embodiments, the metal-containing material is aluminum nitride, and the first metal precursor is an aluminum precursor. In some embodiments, the metal-containing material is gallium nitride, and the first metal precursor is a gallium precursor. In some embodiments, the metal-containing material is indium nitride. and the first metal precursor is an indium precursor. In some embodiments, the metal-containing material is aluminum fluoride, and the first metal precursor is an aluminum precursor. In some embodiments, the metal-containing material is gallium fluoride, and the first metal precursor is a gallium precursor. In some embodiments, the metal-containing material is indium fluoride, and the first metal precursor is an indium precursor.

In some embodiments, the first metal precursor consists of a metal atom bound to an amidinato ligand and two alkyl ligands. In some embodiments, the first metal precursor does not contain a cyclopentadienyl ligand.

In some embodiments, the alkyl ligand attached to the metal atom is selected from a group consisting of methyl, ethyl and linear or branched alkyl groups containing three, four or five carbon atoms. In some embodiments, the first metal precursor comprises two alkyl ligands bonded to the metal atom. In some embodiments, one alkyl ligand is methyl. In some embodiments, one alkyl ligand is ethyl. In some embodiments, one alkyl ligand is n-propyl. In some embodiments, one alkyl ligand is isopropyl. In some embodiments, one alkyl ligand is n-butyl. In some embodiments, one alkyl ligand is isobutyl. In some embodiments, one alkyl ligand is tert-butyl. In some embodiments, one alkyl ligand is sec-butyl. In some embodiments, one alkyl ligand is n-pentyl. In some embodiments, one alkyl ligand is tert-pentyl. In some embodiments, one alkyl ligand is neo-pentyl. In some embodiments, one alkyl ligand is isopentyl. In some embodiments, one alkyl ligand is sec-pentyl. In some embodiments, both alkyl ligands are the same. In some embodiments, both alkyl ligands are methyl. In some embodiments, both alkyl ligands are ethyl. In some embodiments, both alkyl ligands are n-propyl. In some embodiments, both alkyl ligands are isopropyl.

In some embodiments, the amidinato ligand comprises an acetamidinato ligand. In some embodiments, the acetamidinato ligand is an alkylacetamidinato ligand. In some embodiments, the alkylacetamidinato ligand is a dialkylacetamidinato ligand. In some embodiments, the one or two alkyl groups of the alkylacetamidinato ligand are selected from a group consisting of methyl, ethyl, n-propyl, isopropyl, n-butyl, tert-butyl and sec-butyl.

In some embodiments, the first metal precursor is selected from a group consisting of N,N′-di-(isopropylformamidinato)dimethylaluminum, N,N′-di-(isopropylformamidinato)diethylaluminum, N,N′-di-(isopropylformamidinato)-di-n-propylaluminum, N,N′-di-(isopropylformamidinato)-di-tert-butylaluminum and N,N′-di-(isopropylformamidinato)ethylmethylaluminum. In some embodiments, the metal is precursor selected from a group consisting of N,N′-di-(isopropylformamidinato)dimethylindium, N,N′-di-(isopropylformamidinato)diethylindium, N,N′-di-(isopropylformamidinato)-di-n-propylindium, N,N′-di-(isopropylformamidinato)-di-tert-butylindium and N,N′-di-(isopropylformamidinato)ethylmethylindium. In some embodiments, the metal precursor is selected from a group consisting of N,N′-di-(isopropylformamidinato)dimethylgallium, N,N′-di-(isopropylformamidinato)diethylgallium, N,N′-di-(isopropylformamidinato)-di-n-propylgallium, N,N′-di-(isopropylformamidinato)-di-tert-butylgallium and N,N′-di-(isopropylformamidinato)ethylmethylgallium.

In some embodiments, the reactant selected from a group consisting of oxygen precursors, nitrogen precursors and fluorine precursors. In some embodiments, the reactant is selected from a group consisting of ozone (O₃), molecular oxygen (O₂), oxygen atoms (O), an oxygen plasma, oxygen ions, oxygen radicals, oxygen excited species, water (H₂O), and hydrogen peroxide (H₂O₂). In some embodiments, the metal-containing material is a metal oxide, and the reactant is selected from molecular oxygen, ozone, hydrogen peroxide and water. In some embodiments, the metal-containing material is a metal oxide and the reactant is molecular oxygen. In some embodiments, the metal-containing material is a metal oxide and the reactant is ozone. In some embodiments, the metal-containing material is a metal oxide and the reactant is hydrogen peroxide. In some embodiments, the metal-containing material is a metal oxide and the reactant is water.

In some embodiments, the reactant is selected from NH₃ and N₂H₄. In some embodiments, the nitrogen precursor comprises hydrazine. In some embodiments, the nitrogen precursor consists essentially of, or consists of hydrazine. In some embodiments the nitrogen precursor comprises hydrazine substituted by one or more alkyl or aryl substituents. In some embodiments the nitrogen precursor consists essentially of, or consists of hydrazine substituted by one or more alkyl or aryl substituents. In some embodiments, the hydrazine derivative comprises an alkyl-hydrazine including at least one of: tertbutylhydrazine (C₄H₉N₂H₃), methylhydrazine (CH₃NHNH₂), 1,1-dimethylhydrazine ((CH₃)₂NNH₂), 1,2-dimethylhydrazine (CH₃)NHNH(CH₃), ethylhydrazine, 1,1-diethylhydrazine, 1-ethyl-1-methylhydrazine, isopropylhydrazine, tert-butyl-hydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6- dimethylpiperidine, N-aminoaziridine, or azo-tert-butane. In such embodiments, the metal-containing material is metal nitride.

In some embodiments, the reactant is selected from HF, NH₄F, TiF₄ and WF₆. In such embodiments, the metal-containing material is metal fluoride.

Without limiting the current disclosure to any specific theory, the reactant provided into the reaction chamber may react with the first and/or second metal precursor, or a derivative thereof, chemisorbed on the first surface of the substrate to form metal-containing material on the first surface.

The current disclosure relates to a selective deposition process. Selectivity can be given as a percentage calculated by [(deposition on first surface)−(deposition on second surface)]/(deposition on the first surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%. In some embodiments, selectivity is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In embodiments, the selectivity can change over the duration or thickness of a deposition.

In some embodiments, deposition only occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments, selective deposition is inherent, and no additional processing steps over those conveniently performed on a substrate are necessary. However, in some embodiments, the second surface may be passivated before depositing a metal-containing material on the first surface. Selectivity may be inherent to a certain thickness of deposited material, and be lost in case deposition is continued beyond a process-specific threshold. Thus, it may be possible to deposit a metal-containing material of, for example, about 0.1 nm, about 0.5 nm, about 1 nm, about 2 nm, about 3 nm, about 5 nm or about 6 nm before selectivity is lost. The contrast between the first surface and the second surface may be enhanced though passivating the second surface. Alternatively or in addition, intermittent etch-back phase using, for example plasma, such as hydrogen plasma, may be used to keep the process sufficiently selective.

In some embodiments, the second surface is passivated. Thus, in some embodiments, the second surface comprises passivation. A passivation may be performed using an inhibitor reactant, such as a metal halide, or a silylation agent. In some embodiments, either a metal halide or a silylation agent may be used as an inhibitor reactant. The selected inhibitor reactant-which may function as the final passivation of the second surface, or may be used on the first surface to direct the passivation layer on the second surface of the substrate-may have an influence on how selective the subsequent deposition phases are. In some embodiments, the selection of the inhibitor reactant may influence, for example, the roughness of the subsequently deposited layer. In some embodiments, the passivation comprises a passivation layer. In some embodiments, the passivation layer comprises an organic polymer. In some embodiments, the organic polymer comprises polyimide. In some embodiments, the passivation comprises a silylation of the second surface.

In some embodiments, the first surface is a dielectric surface. In some embodiments, the first surface is a low-k surface. By a low k surface is herein meant a surface having at most a similar k value as silicon oxide. In some embodiments, the first surface comprises an oxide. In some embodiments, the first surface comprises a nitride. In some embodiments, the first surface comprises silicon. In some embodiments, the first surface comprises silicon-based dielectric material. Examples of silicon-comprising dielectric materials include silicon oxide-based materials, including grown or deposited silicon dioxide, doped and/or porous oxides and native oxide on silicon. In some embodiments, the first surface comprises silicon oxide. In some embodiments, the first surface is a silicon oxide surface, such as a native oxide surface, a thermal oxide surface or a chemical oxide surface. In some embodiments, the first surface comprises carbon. In some embodiments, the first surface comprises SiN. In some embodiments, the first surface comprises SiOC. In some embodiments, the first surface is an etch-stop layer. An etch-stop layer may comprise, for example a nitride. In some embodiments, the first dielectric surface comprises material selected from a group consisting of SiO₂, SIN, SiC, SiOC, SION, SiOCN, SiGe and combinations thereof.

In some embodiments, the substrate comprises a first dielectric surface and a second metal or metallic surface. In some embodiments, the substrate comprises a first metal-containing material surface. In some embodiments, the first surface may comprise-OH groups. In some embodiments, the first surface may be a SiO₂-based surface. In some embodiments, the first surface may comprise Si—O bonds. In some embodiments, the first surface may comprise a SiO₂-based low-k material. In some embodiments, the first surface may comprise more than about 30%, or more than about 50% of SiO₂. In certain embodiments the first surface may comprise a silicon dioxide surface

In some embodiments, the first surface is a SiO₂ surface and the second surface is a metal surface or an amorphous carbon surface or a metal oxide surface or a metal nitride surface. In some embodiments, the first surface is a SiN surface, and the second surface is a metal surface, such as an elemental metal surface. In some embodiments, the first surface is a SiOC surface, and the second surface is a metal surface. In some embodiments, the first surface is a SiON surface, and the second surface is a metal surface. In some embodiments, the first surface is a SiOCN surface, and the second surface is a metal surface. The second metal surface may be, for example, a copper surface, a ruthenium surface, a tungsten surface, a cobalt surface.

In some embodiments the dielectric material of the first surface comprises a metal oxide. Thus, in some embodiments, a metal-containing material is selectively deposited on a first metal oxide surface relative to a second surface. In some embodiments, the first surface comprises aluminum oxide. In some embodiments, the first surface is a high-k surface, such as hafnium oxide-comprising surface, a lanthanum oxide-comprising surface or a zirconium oxide-comprising surface.

In some embodiments, a metal-containing material is selectively deposited on a first surface comprising a metal-containing material relative to another surface. A metal-containing material surface may be, for example a tungsten oxide (WOx) surface, hafnium oxide (HfOx) surface, titanium oxide (TiOx) surface, aluminum oxide (AlOx) surface or zirconium oxide (ZrOx) surface. In some embodiments, a metal-containing material surface is an oxidized surface of a metallic material. In some embodiments, a metal-containing material surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal-containing material surface is a native oxide formed on a metallic material.

In some embodiments, a metal-containing material, is selectively deposited on a first dielectric surface of a substrate relative to a second conductive (e.g., metal or metallic) surface of the substrate. In some embodiments, the first surface comprises hydroxyl (—OH) groups. In some embodiments, the first surface may additionally comprise hydrogen (—H) terminations, such as an HF dipped Si or HF dipped Ge surface. In such embodiments, the surface of interest will be considered to comprise both the —H terminations and the material beneath the —H terminations. In some embodiments the first surface and the second surface are adjacent to each other.

In some embodiments, the first surface is a dielectric surface and the second surface is a conductive surface. In some embodiments, the second surface comprises a material selected from a group consisting of a metal, amorphous carbon, metal oxide and metal nitride. In some embodiments, the second surface comprises elemental metal. In some embodiments, the second surface consists essentially of, or consists of, elemental metal. In some embodiments, the metal of the second surface is selected from a group consisting of Cu, Co, Ru, W, Ti, Al, Ta, Nb and Mo. In some embodiments, the second surface is an amorphous carbon surface. In some embodiments, the second surface is a metal oxide surface. In some embodiments, the second surface is a metal nitride surface. In other words, in some embodiments, the first surface consists essentially of, or consists of, metal nitride.

In embodiments, in which the first surface is a dielectric surface, the second surface may be selectively passivated before depositing the metal-containing material on the first surface. Thus, in some embodiments, the second surface comprises passivation. In some embodiments, the passivation comprises a passivation layer on the second surface. In some embodiments, the passivation layer comprises an organic polymer. In some embodiments, the organic polymer comprises polyimide.

In some embodiments, passivation, is formed by silylation or metal halide treatment, and it is used to improve contrast between two dielectric surfaces before depositing a metal-containing material on the first dielectric surface. In some embodiments, the first surface is a metal oxide surface, such as a high k surface, and the second surface is a passivated low k surface, such as a silicon-containing surface. In some embodiments, the first surface is hafnium oxide surface and the second surface is a silylated silicon-containing surface. In some embodiments, the first surface is zirconium oxide surface and the second surface is a silylated silicon-containing surface. In some embodiments, the first surface is hafnium zirconium oxide surface and the second surface is a silylated silicon-containing surface. The silicon-containing second surface, such as SiO₂, SIN, SiC, SiON or SiOC surface, may be selectively silylated relative to the first surface by a silylating agent. A silylating agent according to the current disclosure is provided in a vapor phase. In some embodiments, the silicon-containing second surface is silylated by exposure to a silylation agent, such as an alkylsilane, for example allyltrimethylsilane (TMS-A), halosilane, for example chlorotrimethylsilane (TMS-Cl) or octadecyltrichlorosilane (ODTCS), an imidazole, for example N-(trimenthylsilyl)imidazole (TMS-Im), a silazane, for example hexamethyldisilazane (HMDS), or a silylamine, for example N-(trimethylsilyl)dimethylamine or 1,1,1-trimethoxy-N,N-dimethylsilanamine. Silylation may passivate the second dielectric surface against the deposition of the metal-containing material on the first surface.

In some embodiments, the method comprises, before providing the first metal precursor into the reaction chamber, treating the second surface with a silylation agent to passivate the second surface, and thereafter depositing the metal-containing material on the first surface.

In some embodiments, the method comprises, before providing the first metal precursor into the reaction chamber, treating the first surface with a silylation agent, and thereafter depositing an organic polymer on the second surface to passivate the second surface.

### First Surface is a Metal Surface

In some embodiments, the first surface is selected from a metal surface, an amorphous carbon surface, a metal oxide surface and a metal nitride surface. In some embodiments, the first surface comprises a metal.

In some embodiments, the first surface is an elemental metal surface. For the purposes of the current disclosure, an elemental metal surface is a surface that comprises substantially of, or comprises of, an elemental metal. Thus, the oxidation state of the majority of metal atoms in such a surface may be 0. In other words, in some embodiments, the first surface consists essentially of, or consists of, elemental metal.

In some embodiments, the metal of the elemental metal surface is selected from a group consisting of Cu, Co, Ru, W, Ti, Al, Ta, Nb and Mo. In some embodiments, the second surface is a dielectric surface. In some embodiments, the second surface is a metal oxide surface or a silicon-comprising surface. In some embodiments, the second surface comprises a passivation formed by silylating the second surface.

In some embodiments, the first surface is an elemental tungsten (W) surface. In some embodiments, the first surface is titanium nitride (TiN) surface. In some embodiments, the first surface is an elemental tungsten (W) surface, and the second surface is a silicon oxide surface. In some embodiments, the first surface is titanium nitride (TiN) surface, and the second surface is a silicon oxide surface.

In some embodiments, the first surface comprises a metal oxide, such as a high k oxide. In some such embodiments, the metal on the first surface is selected from aluminum oxide, hafnium oxide and zirconium oxide. In some embodiments, the first surface comprises a high k material. In some embodiments, the high k material is selected from a group consisting of hafnium oxide, zirconium oxide and combinations thereof. In some embodiments, the first surface is a hafnium oxide surface. In some embodiments, the first surface is a zirconium oxide surface. In some embodiments, the first surface is a hafnium zirconium oxide surface. In some embodiments, the first surface is hafnium oxide surface and the second surface is a silicon-containing surface. In some embodiments, the first surface is zirconium oxide surface and the second surface is a silicon-containing surface. In some embodiments, the first surface is hafnium zirconium oxide surface and the second surface is a silicon-containing surface.

In embodiments, in which the first surface is a metal surface, the passivation can be performed by silylating the second dielectric surface with a silylating agent. A silylating agent may comprise a silicon atom bonded to a dialkylamine. Thus, the silylating agent has a formula according to formula I:

R₂N-SiR′₃. Formula I:

In some embodiments of Formula I, each R and R′ is independently selected from methyl, ethyl, n-propyl, isopropyl, n-butyl, isobutyl, sec-butyl, tert-butyl, n-pentyl, 1,1-dimethylpropyl, 3-methylbutyl, 1-methylbutyl, 2,2-dimethylpropyl, 1-cthylpropyl, 1,2-dimethylpropyl, 2-methylbutyl, n-hexyl. 1-methylpentyl. 2-methylpentyl, 3-methylpentyl, 4-methylpentyl, 1,1-dimethylbutyl, 1,2-dimethylbutyl, 1.3-dimethylbutyl, 2.2-dimethylbutyl, 3,3-dimethylbutyl, 1-cthylbutyl and 2-ethylbutyl. In some embodiments, each R and R′ is independently selected from methyl, ethyl, n-propyl, isopropyl, n-butyl, isobutyl, sec-butyl and tert-butyl. In some embodiments, both R are the same alkyl. In some embodiments, both R are methyl. In some embodiments, both R are ethyl. In some embodiments, both R are n-propyl. In some embodiments, both R are isopropyl. In some embodiments, all R′ are the same alkyl. In some embodiments, all R′ are methyl. In some embodiments, all R′ are ethyl. In some embodiments. both R′ are n-propyl. In some embodiments. both R′ are isopropyl. In some embodiments, all R and R′ are the same alkyl. In some embodiments. all R and R′ are methyl. In some embodiments, all R and R′ are ethyl. In some embodiments, all R and R′ are n-propyl. In some embodiments. all R and R′ are isopropyl.

In some embodiments of Formula I, at least one of R′ is selected from hydroxyl and C1 to C5 alkoxide groups. In such embodiments, the alkoxide groups are attached to silicon by the oxygen atom. In some embodiment, each alkoxide group is selected from methoxy, ethoxy, n-propoxy, isopropoxy, n-butoxy, isobutoxy and tert-butoxy. In some embodiments, one R′ is selected from hydroxyl and C1 to C5 alkoxide groups. In some embodiments. two R′ are selected from hydroxyl and C1 to C5 alkoxide groups. In some embodiments, three R′ are selected from hydroxyl and C1 to C5 alkoxide groups. In some embodiments. none of the R′ is hydroxyl. In some embodiments. one R′ is hydroxyl. In some embodiments. two R′ are hydroxyl. In some embodiments. three R′ are hydroxyl. In some embodiments. one R′ is hydroxyl and two R′ are methoxy. In some embodiments. one R′ is hydroxyl and two R′ are ethoxy. In some embodiments. one R′ is hydroxyl and two R′ are n-propoxy. In some embodiments, one R′ is hydroxyl and two R′ are isopropoxy. In some embodiments. one R′ is hydroxyl and two R′are n-butoxy. In some embodiments, one R′ is hydroxyl and two R′ are isobutoxy. In some embodiments, one R′ is hydroxyl and two R′ are ser-butoxy. In some embodiments. one R′ is hydroxyl and two R′ are tert-butoxy. In some embodiments. two R′ are hydroxyl and on R′ is methoxy. In some embodiments. two R′ are hydroxyl and one R′ is ethoxy. In some embodiments. two R′ are hydroxyl and one R′ is n-propoxy. In some embodiments. two R′ are hydroxyl and one R′ is isopropoxy. In some embodiments, two R′ are hydroxyl and one R′ is n-butoxy. In some embodiments. two R′ are hydroxyl and one R′ is isobutoxy. In some embodiments, two R′ are hydroxyl and one R′ is sec-butoxy. In some embodiments, two R′ are hydroxyl and one R′ is tert-butoxy. In some embodiments, all three R′ are methoxy. In some embodiments, all three R′ are ethoxy. In some embodiments, all three R′ are n-propoxy. In some embodiments, all three R′ are isopropoxy. In some embodiments, all three R′ are n-butoxy. In some embodiments, all three R′ are isobutoxy. In some embodiments, all three R′ are sec-butoxy. In some embodiments, all three R′ are tert-butoxy.

In embodiments, in which the first surface comprises a metal, amorphous carbon, metal oxide or metal nitride, silylating the second silicon-containing surface with the silylating agent passivates the second surface from deposition of the metal-containing material according to the current disclosure. However, in embodiments, in which the first surface comprises a silicon-containing material, the silylating agent may be used to block the first silicon-containing surface from the deposition of a passivation layer, such as an organic polymer layer. An organic passivation layer, such as a polyimide-containing passivation layer, may be deposited on the second surface that may comprise metal, metal nitride, metal oxide or amorphous carbon. Thus, the deposition of the target metal-containing material, such as an oxide, nitride or fluoride of aluminum, indium or gallium, on the first surface. In some embodiments, the silylation may be removed before the deposition of the metal-containing material.

In some embodiments, alternative passivation agents may be used. For example niobium pentafluoride (NbF₅) may be used to passivate dielectric surfaces. As an example, silicon-containing surfaces, including thermal silicon oxide and native silicon oxide, may be passivated against the deposition of a metal-containing material according to the current disclosure.

The second surface may be covered by passivation layer. In some embodiments, the passivation layer comprises an organic polymer. In some embodiments, the organic polymer comprises polyimide. In some embodiments, silylation and depositing the organic polymer are performed in the same reaction chamber.

The deposition of an organic polymer according to the current disclosure is performed by a cyclic vapor deposition process. For example, the deposition of the organic polymer may be an MLD process. The deposition of an organic polymer comprises providing a first vapor-phase organic precursor into the reaction chamber and providing a second vapor-phase organic precursor into the reaction chamber. Providing a first vapor-phase organic precursor and providing a second vapor-phase organic precursor may define a deposition cycle. The deposition cycle may be repeated until a suitable thickness of the organic polymer has been deposited on the second surface of the substrate. The first and second vapor-phase organic precursors form the organic polymer selectively on the second surface. In some embodiments, the organic polymer comprises polyimide. In some embodiments, the organic polymer comprises polyamide. In some embodiments, the organic polymer forms a passivation layer on the second surface.

Various reactants can be used to deposit organic polymer according to the processes described herein. For example, in some embodiments, the first organic precursor is a diamine. In some embodiments, the first reactant can be, for example, 1,6-diaminohexane, 1,3-diaminopentane, triamine, such as tris(2-aminoethyl)amine, or a cyclic compound comprising at least two primary amine groups, such as 1,4-diaminocyclohexane or p-phenylenediamine. In some embodiments, the substrate is contacted with the first organic precursor before it is contacted with the second organic precursor. Thus, in some embodiments, the substrate may be contacted with a diamine before it is contacted with a second organic precursor.

In some embodiments, the second organic precursor is capable of reacting with adsorbed species of the first reactant under the deposition conditions. For example, in some embodiments, the second organic precursor is an anhydride, such as furan-2,5-dione (maleic acid anhydride). The anhydride can be a dianhydride, e.g., pyromellitic dianhydride (PMDA). In some embodiments, the second reactant can be any other monomer with two reactive groups which will react with the first reactant.

In some embodiments, the organic precursors do not contain metal atoms. In some embodiments, the organic precursors do not contain semimetal atoms. In some embodiments, one of the organic precursors comprises metal or semimetal atoms. In some embodiments, the organic precursors contain carbon and hydrogen and one or more of the following elements: N, O, S, P or a halide, such as Cl or F.

In some embodiments, organic precursors for use in the selective deposition of an organic polymer may be aliphatic compounds comprising 1-6 carbon atoms, 2-5 carbon atoms, 2-4 carbon atoms, 5 or fewer carbon atoms, 4 or fewer carbon atoms, 3 or fewer carbon atoms, or 2 carbon atoms. In some embodiments, the bonds between carbon atoms in the reactant or precursor may be single bonds, double bonds, triple bonds, or some combination thereof. Thus, in some embodiments, a first organic precursor may comprise two amino groups. In some embodiments, the amino groups of a first organic precursor may occupy one or both terminal positions on an aliphatic carbon chain. However, in some embodiments, the amino groups of a first organic precursor may not occupy either terminal position on an aliphatic carbon chain. In some embodiments, a first organic precursor may comprise a diamine. In some embodiments, a first organic precursor may comprise an organic precursor selected from the group of 1,2-diaminoethane, 1,3-diaminopropane, 1,4-diaminobutane, 1.5-diaminopentane, 1,2-diaminopropane, 2,3-butanediamine, 2,2-dimethyl-1,3-propanediamine.

In some embodiments, a first and/or second organic precursor has a vapor pressure greater than about 0.5 Torr, 0.1 Torr, 0.2 Torr, 0.5 Torr, 1 Torr, 2 Torr or greater at a temperature of about 20° C. or room temperature. In some embodiments, a first and/or second organic precursor has a boiling point less than about 400° C., less than 300° C., less than about 250° C., less than about 200° C., less than about 175° C., less than about 150° C., or less than about 100° C.

In some embodiments, the first organic precursor provided into the reaction chamber at 210a is a liquid precursor under standard conditions. In some embodiments, the first organic precursor being vaporized comprises a diamine, such as 1,6-diaminohexane, 1,3-diaminopentane, triamine, such as tris (2-aminoethyl) amine, or a cyclic compound comprising at least two primary amine groups, such as 1,4-diaminocyclohexane or p-phenylenediamine. The substrate is then exposed to the first organic precursor vapor 210a. The substrate is also exposed to a second vapor-phase precursor 210b, for example an organic precursor, such as a dianhydride. A dianhydride may be, for example, pyromellitic dianhydride (PMDA). The cyclic exposure of the substrate to the first and second organic precursors leads to the deposition of an organic polymer. The method can include additional steps, and may be repeated, but need not be performed in the illustrated sequence nor the same sequence in each repetition, and can be readily extended to more complex vapor deposition techniques.

The first organic precursor according to the current disclosure may comprise at least two carbon atoms, such as 1,2-diaminoethane. In some embodiments, first organic precursor comprises three carbon atoms. In some embodiments, first organic precursor comprises four carbon atoms. For example, first organic precursor may be selected from 1,2-diaminobutane, 1,3-diaminobutane, 1,4-diaminobutane and 2,4-diaminobutane. Thus, in some embodiments, at least one of the amino groups is attached to a carbon atom that is bonded to two other carbon atoms. In other words, at least one of the amino groups may be located at the end of a carbon chain. In some embodiments, a diamine according to the current comprises five carbon atoms. In some embodiments, a diamine according to the current comprises six carbon atoms.

In some embodiments, the carbon chain of the first organic precursor is branched. Thus, there is at least one carbon atom which is bonded to three or four other carbon atoms. In some embodiments, there is one such branching position in the first organic precursor. In some embodiments, there are two such branching positions in the first organic precursor. In some embodiments, there are three or more branching points. In some embodiments, the side chain from the longer carbon chain is a methyl group. In some embodiments, the side chain from the longer carbon chain is an ethyl group. In some embodiments, the side chain from the longer carbon chain is a propyl group. In some embodiments, the side chain from the longer carbon chain is an isopropyl group. In some embodiments, the side chain from the longer carbon chain is a butyl group. In some embodiments, the side chain from the longer carbon chain is a tert-butyl group. In some embodiments, a side chain of a first organic precursor is a straight alkyl chain. In some embodiments, a side chain of a first organic precursor is a branched alkyl chain. In some embodiments, a side chain of a first organic precursor is a cyclic alkyl chain.

In some embodiments, the first organic precursor is a C2 to C11 compound. The number of carbon atoms in the first organic precursor typically influences the volatility of the compound such that a higher-weight compound may not be as volatile as a smaller compound. However, it was found out that intermediate-sized first organic precursors containing, for example, four, five or six carbon atoms, may have suitable properties for being used as a first organic precursor in the selective deposition processes according to the current disclosure. For example, 1,3-diaminopentane is liquid at room temperature, has a boiling point of 164° C. under atmospheric pressure, a vapor pressure of about 2.22 Torr at 25° C. and reaches a vapor pressure of 1 Torr at temperatures below 20° C. Thus, when 1,3-diaminopentane is used as a precursor for organic polymer deposition according to the current disclosure, the precursor vessel does not need to be heated. This may be advantageous for the on-tool lifetime of the precursor, as it may be less prone to degradation during continued use. Further, a liquid precursor has an advantage that precursor vessel loading is less expensive than for solid precursors. In some embodiments, the first organic precursor comprises 1,3-diaminopentane.

In some embodiments of the disclosure, the amine groups are attached to non-adjacent carbon atoms. This may have advantages for the availability for the amine groups to reactions with the second precursor. In some embodiments, there is one carbon atom between the amino group-binding carbon atoms. In some embodiments, there is at least one carbon atom between the amino group-binding carbon atoms. In some embodiments, there are two carbon atoms between the amino group-binding carbon atoms. In some embodiments, there are at least two carbon atoms between the amino group-binding carbon atoms. In some embodiments, there are three carbon atoms between the amino group-binding carbon atoms. In some embodiments, there are at least three carbon atoms between the amino group-binding carbon atoms. In some embodiments, there are four carbon atoms between the amino group-binding carbon atoms. In some embodiments, there are at least four carbon atoms between the amino group-binding carbon atoms.

In some embodiments, the first organic precursor comprises 1,5-diamino-2-methylpentane.

In some embodiments, a carbon atom bonded with an amine nitrogen in the first organic precursor is bonded to at least two carbon atoms. Thus, in some embodiments in which the first organic precursor comprises five or more carbons, at least one of the amino groups may be located away from the end of a carbon chain. The structure of the first organic precursor affects its properties in a vapor deposition process. Branching of a first organic precursor, including the number of branches, and the relative position of the amino groups to the branches, may cause the deposited organic polymer to have different properties. Without limiting the current disclosure to any specific theory, for example steric factors, may lead to certain reactions being preferred in This may offer the possibility to design a deposition process for a given purpose, taking into account for example the thermal budget, organic polymer growth speed requirements, necessary degree of selectivity, by using different first organic precursors.

In some embodiments, the first organic precursor is a cyclic diamine. In some embodiments, the fist organic precursor comprises a cyclopentanedialkylamine, cyclohexanedialkylamine, cyclopentadienedialkylamine, benzenedialkylamine, cyclopentanetrialkylamine, cyclohexanetrialkylamine, cyclopentadienetrialkylamine and benzenetrialkylamine.

In some embodiments, the first organic precursor is an aromatic diamine. In some embodiments, the aromatic diamine is a diaminobenzene, such as 1,2-diaminobenzene, 1,3-diaminobenzene or 1,4-diaminobenzene. In some embodiments, the aromatic diamine comprises an alkylamino group in at least one position. For example, the alkylamino group may be a C1 to C3alkylamino group, such as —CH₂NH₂, —(CH₂)₂NH₂, —(CH₂)₃NH₂, —CH(CH₃)NH₂ or —CH₂CH(CH₃)NH₂.

In some embodiments, the first organic precursor is selected from a group consisting of 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene and 1,4-diaminobenzene. In some embodiments, the first organic precursor comprises a halogen.

In some embodiments, triamines may be used in the deposition of organic polymer according to the current invention. Providing such molecules may advantageously affect the availability of polymerization sites for the second vapor-phase organic precursor. The availability of three amine groups in a single molecule, may lead to denser polymer network, which again may reduce the metal migration through the organic polymer. Such properties may be advantageous in embodiments utilizing the organic polymer according to the current disclosure as a passivation layer. Examples of suitable triamines include 1,2,3-triaminopropane, triamino butane (with amines in carbons 1, 2 and 3 or in carbons 1, 2 and 4), triamino pentane (especially with amines in carbons 1 and 5, plus in any one of the carbons 2, 3 or 4). Similarly, triamino hexanes may contain amine groups in carbons 1 and 6, as well as in any one of the positions 2, 3, 4 or 5; triamino heptanes may contain amine groups in carbons 1 and 7, as well as in any one of the positions 2. 3, 4, 5 or 6; and triamino octanes may contain amine groups in carbons 1 and 8, as well as in any one of the positions 2, 3, 4, 5, 6 or 7. Further, branched carbon chains, notably 2-aminomethyl-1,3-diaminopropane, 2-aminomethyl-1,4-diaminobutane (or alternatives having the two amino groups elsewhere in the butane chain), 2-aminomethyl-1,5-diaminopentane (or alternatives having the two amino groups elsewhere in the pentane chain), 3-aminomethyl-1,5-diaminopentane (or alternatives having the two amino groups elsewhere in the pentane chain), 2-aminomethyl-1,6-diaminohexane (or alternatives having the two amino groups elsewhere in the hexane chain), 3-aminomethyl-1,6-diaminohexane (or alternatives having the two amino groups elsewhere in the hexane chain), 3-aminoethyl-1,6-diaminohexane (or alternatives having the two amino groups elsewhere in the hexane chain). Also, an aromatic triamine, such as 1,3,5-triaminobenzene, may be an alternative for certain embodiments.

In some embodiments, the polymer deposited comprises polyimide. In some embodiments, the organic polymer consists substantially only of polyimide. In some embodiments, the organic polymer comprises polyamic acid. In some embodiments, the organic polymer consists substantially only of polyamic acid and polyimide. In some embodiments, the organic polymer is deposited at temperatures below 190° C., and subsequently heat-treated (annealed) at a temperature of about 190° C. or higher (such as from about 200° C. to about 500° C.) to increase the proportion of the organic polymer from polyamic acid to polyimide. Other examples of deposited polymers include dimers, trimers, polyurethanes, polythioureas, polyesters, polyimines, other polymeric forms or mixtures of the above materials.

In some embodiments the substrate is thermally annealed for a period of about 1 to about 15 minutes. In some embodiments the substrate is thermally annealed at a temperature of about 200 to about 500° C. In some embodiments the thermal anneal step comprises two or more steps in which the substrate is thermally annealed for a first period of time at a first temperature and then thermally annealed for a second period of time at a second temperature.

In some embodiments, the deposited organic polymer is exposed to reactive species generated from plasma. This may improve the passivation properties of the organic polymer in embodiments in which it is used as a passivation material. For example, reactive species generated from hydrogen-and argon-comprising plasma can be used. The organic polymer may be exposed to plasma from about 1seconds to about 1 minute, such as from about 1 second to about 30 seconds, or from about 5 seconds to about 30 seconds, or for about 1 second to about 15 seconds, or from about 3 seconds to about 20 seconds, for example for about 5 seconds, for about 10 seconds, for about 20 seconds or for about 30 seconds. A plasma power of at least about 20 W, or at least about 50 W, such as from about 20 W to about 100 W, such as 30 W, 50 W or 70 W, may be used. The suitable plasma power and duration of the plasma exposure may be determined experimentally.

### Drawings

The disclosure is further explained by the following exemplary embodiments depicted in the drawings. The illustrations presented herein are not meant to be actual views of any particular material. structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. Specifically, relative deposition rates of different materials indicated in the drawings may deviate from the experimental results, the specifics of which may vary according to process conditions. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

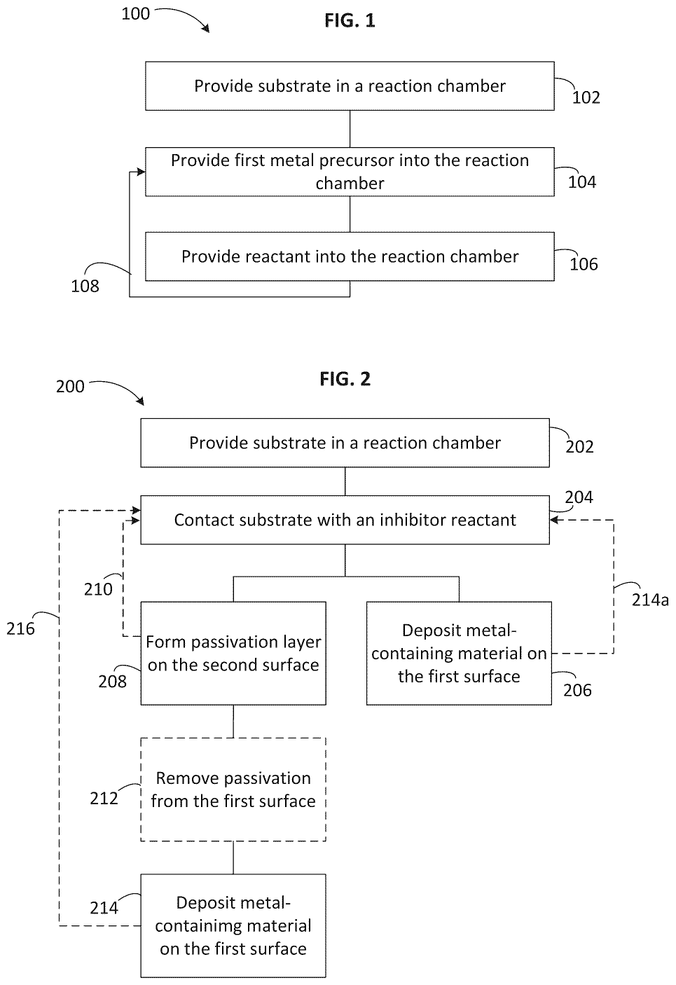

FIG. 1 is a block diagram of an exemplary embodiment of a method 100 according to the current disclosure. First, a substrate is provided in a reaction chamber at block 102. The substrate comprises a first surface and a second surface as described in the current disclosure. For example, the first surface may be a dielectric surface, and the second surface may be a metal or a metallic surface. In some embodiments, the first surface is a high k surface, and the second surface is a silicon-containing dielectric surface, such as a low k surface. In some embodiments, the first surface is a metal surface, a metallic surface, an amorphous carbon surface, a metal oxide surface or a metal nitride surface (e.g. a metallic surface), and the second surface is a dielectric surface, such as a silicon-containing surface. The substrate may be heated at block 102 prior to providing a first metal precursor into the reaction chamber.

At block 104, a first metal precursor is provided into the reaction chamber in a vapor phase. In an exemplary embodiment, the first metal precursor is an aluminum precursor as disclosed herein. For example, the aluminum precursor may comprise, consist essentially of, or consist of, N,N′-di-(isopropylformamidinato)dimethylaluminum. The first metal precursor is selectively chemisorbed on the first surface relative to the second surface of the substrate. The first metal precursor may be provided into the reaction chamber (i.e. pulsed) for about 0.2 to 10 seconds, for example, about 0.5 seconds, about 1 second, about 3 seconds, about 5 seconds or about 6 seconds. The reaction chamber may be purged after a first metal precursor pulse. Purging is not indicated in FIG. 1, but it may be optionally included in block 104.

At block 106, a reactant is provided into the reaction chamber in a vapor phase. The reactant reacts with the chemisorbed first metal precursor or a derivative thereof to form metal-containing material on the first surface of the substrate. In an exemplary embodiment, the reactant is water, and aluminum oxide is deposited on the first surface. In another exemplary embodiment, the reactant is ammonia, and aluminum nitride is deposited on the first surface. The reaction chamber may be purged after a reactant pulse. Purging is not indicated in FIG. 1, but it may be optionally included in block 106.

The deposition process according to the current disclosure is a cyclic deposition process. Thus, phases 104 and 106 form a deposition cycle. At loop 108, the deposition cycle is initiated again. The deposition cycle may be repeated as many times as needed to deposit a metal-containing material of desired thickness on the first surface of the substrate. For example, the deposition cycle may be performed from 2 to about 600 times, or from 2 to about 500 times, or from about 5 to about 200 times, or from about 10 to 300 times. For example, the deposition cycle may be performed about 30 times, about 50 times, about 100 times, about 150 times, about 200 times, about 300 times or about 400 times.

The deposition temperature, such as the temperature of the reaction chamber or the substrate support, may be from about 150° C. to about 450° C. or from about 200° C. to about 400° C., or from about 300° C. to about 400° C. For example, the deposition temperature may be about 250° C. or about 300° C. or about 350° C. or about 375° C. In some embodiments, in which passivation is used, the second surface of the substrate is passivated at a lower temperature as the deposition temperature for the metal-containing material.

Although not detailed in the current disclosure, the process may comprise additional steps, for example refreshing any blocking or passivation that may be necessary for the continued selective deposition, thermal treatments, intermediate etch-back or post-deposition etching. In some embodiments, the selective deposition of a metal-containing material on the first surface does not damage a passivation, such as an organic passivation layer, for example a polyimide comprising layer, present on the second surface. Further, in some embodiments, metal-containing material is substantially not deposited on the passivation. Although not depicted in FIGS. 1 to 4, it is possible for the phases of the deposition process to overlap. For example, phases 104 and 106 may be performed at least partially simultaneously. In some embodiments, phases 104 and 106 are performed at least partially simultaneously.

FIG. 2 is a block diagram of another exemplary embodiment of a method according to the current disclosure illustrating the selection of a deposition surface (i.e. first surface) between metal and metallic materials on the one hand, and dielectric materials on the other. Block 202 corresponds to block 102 of FIG. 1, and blocks 206 and 212 represent the subject matter of blocks 104, 106 and 108 of FIG. 1.

In the flow of FIG. 2, block 202 is followed by contacting the substrate with an inhibitor reactant at block 204. The inhibitor reactant may be, for example, a silylating agent or a metal halide as described herein. As the substrate is contacted with the inhibitor reactant, the inhibitor reactant reacts with either the first surface or the second surface, depending on their composition. The inhibitor reactant forms passivation on the surface. Typically, a silylating agent reacts with a silicon-containing surface or with other non-conductive surface. If the surface that is passivated by the inhibitor reactant is the surface on which no deposition is desired (i.e. second surface), the process may be continued to block 206. If needed, contacting with an inhibitor reactant may be repeated by returning to block 204 through loop 214a. Blocks 204 and 206 may be performed in one reaction chamber, in two deposition stations of a multi-station reaction chamber, in different reaction chambers of one deposition assembly, or in different deposition assemblies. In some embodiments, there is no air-break between blocks 204 and 206. In some embodiments, there is an air-break between blocks 204 and 206. In some embodiments, a metal-containing material is selectively deposited on a first dielectric surface of a substrate relative to a second, different dielectric surface

In embodiments, in which the metal-containing material is targeted on the same surface which is passivated by the inhibitor reactant, the initial passivation by the inhibitor reactant may be utilized to deposit an passivation layer on the other (i.e. second) surface of the substrate. In such embodiments, the process of FIG. 2 continues to block 208. Block 208 may comprise a cyclic deposition process, such as an MLD process to deposit an organic polymer, such as a polyimide, as described herein. Similarly to block 206, the initial passivation may be renewed by returning from block 208 to the earlier block 204, as indicated by the dashed arrow 210. This may happen at predetermined intervals that may be developed for each application. After a passivation layer has been deposited, the initial passivation from the first surface may be removed at the optional block 212, after which the metal-containing material may be deposited on the first surface at block 214. As indicated by the optional loop 216, the passivation may be performed ed again by returning to block 204. Although not indicated in FIG. 2, passivation may be performed again by returning to block 208.

The second surface may be passivated. For example, a second metallic surface may comprise a polyimide-comprising passivation layer thereon. Alternatively, as second dielectric, such as a silicon oxide, surface may comprise silylation. In exemplary embodiments, the substrate may comprise a silicon oxide surface and a tungsten surface, or a silicon oxide surface and a titanium nitride surface, or a silicon oxide surface, a tungsten surface and a silicon oxide surface. The silicon oxide surface may be passivated using a silylating agent, such as N-(trimethylsilyl)dimethylamine or 1,1,1-trimethoxy-N,N-dimethylsilanamine. Thereafter, aluminum oxide may be deposited on the tungsten surface and/or titanium nitride surface, depending on their presence on the substrate. The deposition of aluminum oxide may be performed by providing a first metal precursor, such as N,N′-di-(isopropylformamidinato)dimethylaluminum, and a reactant, such as water, alternately and sequentially into the reaction chamber at a temperature of, for example, 300° C. The growth of the target material (such as aluminum oxide) may be delayed on the second surface. For example, the deposition may be performed up to more than about 100 cycles before growth on the second surface is initiated. This cycle number (sometimes termed selectivity window) may be increased by, for example, intermittent etching.

In an alternative process flow, the silylation may be performed as described above, but it will be followed by the deposition of an organic polymer, such as a polyimide-comprising polymer, as described herein. In such an embodiment, the tungsten and/or metal nitride surface present on the substrate will be the second surface, while the silicon oxide surface is the first surface, on which the aluminum oxide is deposited. The first metal (tungsten and/or titanium nitride) surface may be activated by removing the silylation but not the organic polymer prior to the deposition of aluminum oxide or another metal oxide or a metal nitride. After a sufficient amount of the target material has been deposited on the first surface, the organic polymer passivation may be removed from the second surface, for example by plasma. In some embodiments, at least 3 nm of metal oxide, such as aluminum oxide, is grown on the first metal-comprising surface before growth is initiated on a second silicon oxide surface.

Metal nitride, such as aluminum nitride, films can be deposited using a similar process as described above. The selectivity of the process was tested also on hafnium oxide (HfO₂) surface, on which the growth of metal-containing material, exemplified by aluminum nitride, was inhibited by silylation. In some embodiments, the deposition of the metal-containing material may be done at a temperature of about 350° C. or at a temperature of about 375° C. using ammonia (NH₃) as the reactant with the aluminum precursor as described above. The pulse time of the first metal precursor may be from about 1 seconds(s) to about 8 s, such as about 3 s, 5 s or 7 s. In some embodiments, the reactant, i.e. ammonia pulse time is the same or longer than the first metal precursor pulse time. For example, the reactant pulse time may be from about 5 s to about 30 s, such as 10 s or 15 s. Without limiting the current disclosure to any specific theory, the selectivity of the metal nitride process, such as aluminum nitride process, may be better than that of the metal oxide process.

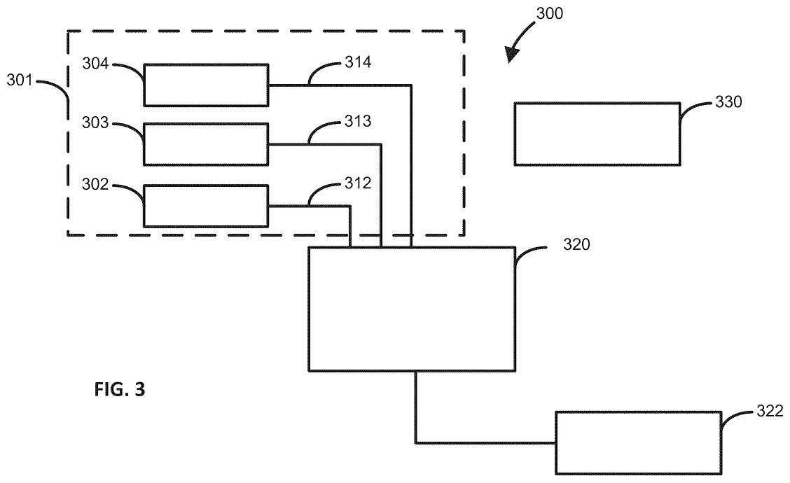

FIG. 3 is a schematic drawing of an embodiment of a semiconductor processing assembly according to the current disclosure.

In yet another aspect, a semiconductor processing assembly 300 for selectively depositing a metal-containing material on a first surface of a substrate relative to a second surface of the substrate is disclosed. The semiconductor processing assembly 300 comprises one or more reaction chambers 320 constructed and arranged to hold the substrate and a precursor injector system 301 constructed and arranged to provide a first metal precursor comprising a group 13 metal atom, an amidinato ligand and an alkyl ligand attached to the metal atom, and a reactant into the reaction chamber 320 in a vapor phase. The semiconductor processing assembly 300 further comprises a first metal precursor source vessel 302 and a reactant source vessel 303. The precursor injector system 301 is constructed and arranged to provide the first metal precursor and the reactant into the reaction chamber 320 in a vapor phase. The first metal precursor and the reactant may be provided into the reaction chamber alternately and sequentially to form a metal-containing material on the first surface.

The semiconductor processing assembly 300 further comprises an optional inhibitor reactant source vessel 304 constructed and arranged to contain an inhibitor reactant according to the current disclosure. The semiconductor processing assembly 300 is constructed and arranged to provide the inhibitor reactant via the precursor injector system 301 into the reaction chamber 320 for selectively forming inhibitor material on the first surface or on the second surface of the substrate.

The processing assembly 300 may comprise optional further source vessels constructed and arranged to contain additional reactants used in the processing of the substrate. For example, a further source vessel may be constructed and arranged to hold a second inhibitor reactant, a precursor for forming a passivation layer, or an etchant. The precursors may be organic precursors for depositing a passivation layer on the second surface of the substrate.

The processing assembly 300 is configured and arranged to perform a method as described herein. In the illustrated example, the semiconductor processing assembly 300 includes one or more reaction chambers 320, a precursor injector system 301, source vessels 302, 303, 304, optional and further source vessels, an exhaust source 322, and a controller 330. The processing assembly 300 may comprise one or more additional gas sources (not shown), such as an inert gas source, a carrier gas source and/or a purge gas source. Reaction chamber 320 can include any suitable reaction chamber, such as an ALD or CVD reaction chamber as described herein.

The first metal precursor source vessel 302 can include a vessel and a first metal precursor as described herein-alone or mixed with one or more carrier (e.g., inert) gases. The reactant source vessel 303 can include a vessel and a reactant as described herein-alone or mixed with one or more carrier (e.g., inert) gases. Thus, although illustrated with three source vessels 302-304, a processing assembly 300 can include any suitable number of source vessels. Source vessels 302-304 can be coupled to reaction chamber 320 via lines 312-314, which can each include flow controllers, valves, heaters, and the like. In some embodiments, each of the source vessels 302-304 may be independently heated or kept at ambient temperature. In some embodiments, a source vessel is heated so that a precursor or a reactant reaches a suitable temperature for vaporization

Exhaust source 322 can include one or more vacuum pumps.

Controller 330 includes electronic circuitry and software to selectively operate valves, manifolds, heaters, pumps and other components included in the processing assembly 300. The controller is programmed to execute a method as disclosed herein. Such circuitry and components operate to introduce precursors, reactants and other gases from the respective sources. Controller 330 can control timing of gas pulse sequences, temperature of the substrate and/or reaction chamber 320, pressure within the reaction chamber 320, and various other operations to provide proper operation of the processing assembly 300. Controller 330 can include control software to electrically or pneumatically control valves to control flow of precursors, reactants and other gases into and out of the reaction chamber 320. Controller 330 can include modules such as a software or hardware component, which performs certain tasks.

Other configurations of processing assembly 300 are possible, including different numbers and kinds of precursor and source vessels. For example, a reaction chamber 320 may comprise more than one, such as two or four, deposition stations. Such a multi-station configuration may have advantages if, for example, inhibition, passivation, deposition and/or etching are to be performed in the same reaction chamber. Further, it will be appreciated that there are many arrangements of valves, conduits, precursor sources, and reactant sources that may be used to accomplish the goal of selectively and in coordinated manner feeding gases into reaction chamber 320. Further, as a schematic representation of a processing assembly 300, many components have been omitted for simplicity of illustration, and such components may include, for example, various valves, manifolds, purifiers, heaters, containers, vents, and/or bypasses.

During operation of processing assembly 300, substrates, such as semiconductor wafers (not illustrated), are transferred from, e.g., a substrate handling system to reaction chamber 320. Once substrate(s) are transferred to reaction chamber 320 (i.e. they are provided in the reaction chamber 320), one or more gases from gas sources, such as precursors, reactants, carrier gases, and/or purge gases, are introduced into reaction chamber 320.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method of selectively depositing a metal-containing material on a first surface of a semiconductor substrate relative to a second surface of the substrate; the method comprising
providing the substrate in a reaction chamber; and
depositing the metal-containing material on the first surface of the substrate by a cyclic vapor deposition process, wherein the cyclic vapor deposition process comprises
providing a first metal precursor into the reaction chamber in a vapor phase; and
providing a reactant into the reaction chamber in a vapor phase,
wherein the first metal precursor comprises a heteroleptic precursor comprising a group 13metal atom, an amidinato ligand and an alkyl ligand attached to the metal atom.

2. The method of claim 1, wherein the metal-containing material includes a metal selected from a group consisting of aluminum (Al), gallium (Ga) and indium (In).

3. The method of claim 2, wherein the metal-containing material is aluminum oxide, and the first metal precursor is an aluminum precursor.

4. The method of claim 2, wherein the metal-containing material is aluminum nitride, and the first metal precursor is an aluminum precursor.

5. The method of claim 1, wherein the alkyl ligand attached to the metal atom is selected from a group consisting of methyl, ethyl and linear or branched alkyl groups containing three, four or five carbon atoms.

6. The method of claim 5, wherein the first metal precursor comprises two alkyl ligands bonded to the metal atom.

7. The method of claim 6, wherein the amidinato ligand is an alkylacetamidinato ligand.

8. The method of claim 7, wherein the alkylacetamidinato ligand is a dialkylacetamidinato ligand.

9. The method of claim 7, wherein the one or two alkyl groups of the alkylacetamidinato ligand are selected from a group consisting of methyl, ethyl, n-propyl, isopropyl, n-butyl, tert-butyl and sec-butyl.

10. The method of claim 9, wherein the first metal precursor is selected from a group consisting of N,N′-di-(isopropylformamidinato)dimethylaluminum, N,N′-di-(isopropylformamidinato)diethylaluminum, N,N′-di-(isopropylformamidinato)-di-n-propylaluminum, N,N′-di-(isopropylformamidinato)-di-tert-butylaluminum and N,N′-di-(isopropylformamidinato)ethylmethylaluminum.

11. The method of claim 1, wherein the reactant is selected from a group consisting of oxygen precursors, nitrogen precursors and fluorine precursors.

12. The method of claim 1, wherein the reactant is selected from a group consisting of molecular oxygen, ozone, hydrogen peroxide and water.

13. The method of claim 1, wherein the first surface is a silicon-containing dielectric surface.

14. The method of claim 13, wherein the a silicon-containing dielectric surface comprises material selected from a group consisting of SiO₂, SiN, SiC, SiOC, SiON, SiOCN, SiGe and combinations thereof.

15. The method of claim 1, wherein the first surface is a dielectric surface comprising a metal oxide.

16. The method of claim 15, wherein the metal oxide of the second surface is selected from aluminum oxide, hafnium oxide and zirconium oxide.

17. The method of claim 1, wherein the second surface is a conductive surface.

18. The method of claim 1, wherein the second surface comprises a material selected from a group consisting of a metal, amorphous carbon, metal oxide and metal nitride.

19. The method of claim 1, wherein the second surface comprises elemental metal.

20. The method of claim 1, wherein the method comprises, before providing the first metal precursor into the reaction chamber, treating the first surface with an inhibitor reactant and thereafter depositing an organic polymer on the second surface to passivate the second surface.

21. The method of claim 1, wherein the first surface is an elemental metal surface or a metal nitride surface.

22. The method of claim 21, wherein the second surface is a dielectric surface.
